(19) United States
(12) Patent Application Publication
(10) Pub. No.: US 2012/0064699 A1
(43) Pub. Date: Mar. 15, 2012

(54) METHODS AND SYSTEMS FOR SPRAY PYROLYSIS WITH ADDITION OF VOLATILE NON-POLAR MATERIALS

(75) Inventors: Yuriy B. Matus, Pleasanton, CA (US); Roman Mostovoy, San Francisco, CA (US)

(73) Assignee: Alion, Inc., Richmond, CA (US)

(21) Appl. No.: 13/226,190

(22) Filed: Sep. 6, 2011

Related U.S. Application Data
(60) Provisional application No. 61/380,976, filed on Sep. 8, 2010.

(51) Int. Cl. H01L 21/20; B05B 15/00; B05B 1/00

(52) U.S. Cl. 438/478; 118/58; 118/620; 257/E21.09

(57) ABSTRACT

Method and system for forming a cadmium-sulfide layer on a substrate. The method includes preparing a solution and loading the solution into a pyrolysis-deposition system. The solution uses at least one cadmium-containing solute, at least one sulfur-containing solute, water, and at least one selected material. The pyrolysis-deposition system includes one or more nozzles and one or more heating devices. The method further includes placing a substrate into the pyrolysis-deposition system, adjusting a distance between the substrate and the one or more nozzles, heating the substrate with the one or more heating devices, and spraying the solution including the selected material towards the substrate. The selected material satisfies at least one property selected from a group consisting of the selected material being non-polar, the selected material having at least higher volatility than water, and the selected material having at least lower heat capacity than water.

### 1. CROSS-REFERENCES TO RELATED APPLICATIONS

This application claims priority to U.S. Provisional Application No. 61/380,976, filed Sep. 8, 2010, commonly assigned and incorporated by reference herein for all purposes.

The following two commonly-owned co-pending applications, including this one, are being filed concurrently and the other one is hereby incorporated by reference in its entirety for all purposes.

1. U.S. patent application Ser. No. ______, titled “Methods and Systems for Spray Pyrolysis with Addition of Volatile Non-Polar Materials,” (Attorney Docket Number 012805-0010-999); and

2. U.S. patent application Ser. No. ______, titled “Methods and Systems for Forming Functionally Graded Films by Spray Pyrolysis,” (Attorney Docket Number 012805-0012-999).

### 2. BACKGROUND OF THE INVENTION

The present invention is directed to deposition of films using spray pyrolysis. More particularly, the invention provides methods and systems for spray pyrolysis with addition of one or more volatile non-polar materials. Merely by way of example, the invention has been applied to the spray pyrolysis of CdS films for photovoltaic modules. But it would be recognized that the invention has a much broader range of applicability.

Various CdS deposition techniques can be used in the making of thin-film photovoltaic modules (e.g., solar cells). For example, these CdS deposition techniques can be divided into two groups—deposition techniques that use vacuum systems and deposition techniques that use non-vacuum systems. The deposition techniques that use vacuum systems can fabricate CdS thin films that have excellent properties, but these techniques also require expensive and complex equipment. The deposition techniques that use non-vacuum systems include a chemical bath deposition (CBD) technique and a spray pyrolysis technique. For example, the CBD technique provides excellent film quality, but the CBD technique suffers from low chemical utilization and also needs extensive waste treatment. In another example, the conventional spray pyrolysis technique provides excellent film quality, but the conventional spray pyrolysis technique suffers from a low equipment throughput (i.e., low deposition rate).

FIG. 1 is a simplified diagram of a conventional system for deposition of thin films on a substrate using spray pyrolysis. For example, the spray pyrolysis apparatus 100 uses one or more spray nozzles 110 to spray a pyrolysis solution 120 towards a substrate 130 positioned via a substrate holder 150. Each droplet of the pyrolysis solution 120 includes a solvent and one or more solutes depending upon the type of thin film to be deposited on the substrate 130. Various modes are used to obtain the thin film using spray pyrolysis. In one mode, as one or more droplets of the pyrolysis solution 120 approach the surface of the substrate 130, the solvent vaporizes and the one or more solutes become one or more vapors. Then, the one or more vapors form a film on the surface of the substrate 130. In another mode, one or more droplets of the pyrolysis solution 120 reach the surface of the substrate 130. Then, with the solvent still present on the surface of the substrate 130, a film is formed on the surface of the substrate 130. It is also possible for both of the two modes described above to occur in the same deposition process. The spray pyrolysis also utilizes a gas supply 170 made available to the one or more spray nozzles 110 to atomize the pyrolysis solution 120 and/or to control the flow of the pyrolysis solution through the one or more spray nozzles 110 towards the substrate 130. For example, nitrogen gas is often used.

Various techniques have been used to control the deposition modes for spray pyrolysis. For example, the temperature of the substrate 130 is adjusted through the use of one or more heating elements 140 to control the vaporization of the solvents in the pyrolysis solution 120. In another example, adjusting the distance between the one or more spray nozzles 110 and the substrate 130 controls the extent to which the gasification of the one or more solutes occurs above or on the surface of the substrate 130. In yet another example, overspray can be reduced and material utilization can be increased by the introduction of a bias voltage 160 between the one or more spray nozzles 110 and the substrate 130.

Conventional spray pyrolysis, however, has its limitations. For example, while the use of the one or more heating elements 140 with the conventional pyrolysis solution 120 may improve the deposition rate, and thus the production rates of the thin films on the substrate 130, it is not without practical limits. Heating the substrate 130 to high temperatures with the one or more heating elements 140 often has a high energy cost. It can further increase the likelihood that the substrate 130 will crack during the pyrolysis process. Thus, it would be helpful if the same deposition rates could be obtained at a lower temperature, which can lower energy costs and/or reduce the likelihood of substrate 130 cracking. Alternatively, if improved deposition rates could be obtained at conventional temperatures, this would improve production rates and consequently reduce per-unit energy costs. Additionally, conventional spray pyrolysis usually has low chemical utilization due to large overspray. Even the introduction of the bias voltage 160 with a conventional pyrolysis solution 120 can improves material utilization by, for example, 30-50%. Also, the one or more spray nozzles 110 are prone to clogging in the conventional spray pyrolysis process.

Hence, it is highly desirable to improve techniques for the deposition of thin films using spray pyrolysis.

### 3. BRIEF SUMMARY OF THE INVENTION

The present invention is directed to deposition of films using spray pyrolysis. More particularly, the invention provides methods and systems for spray pyrolysis with addition of one or more volatile non-polar materials. Merely by way of example, the invention has been applied to the spray pyrolysis of CdS films for photovoltaic modules. But it would be recognized that the invention has a much broader range of applicability.

According to at least one embodiment, a method for forming a cadmium-sulfide layer on a substrate includes preparing a solution and loading the solution into a pyrolysis-deposition system. The solution uses at least one cadmium-containing solute, at least one sulfur-containing solute, water, and at least one selected material. And the pyrolysis-deposition system includes one or more nozzles and one or more heating devices. The method for forming a cadmium-sulfide layer on a substrate further includes placing a substrate into the pyrolysis-deposition system, adjusting a distance between the substrate and the one or more nozzles, heating the substrate with the one or more heating devices, and spraying the solution including the selected material towards the substrate. The method forms a cadmium-sulfide layer on a substrate. The selected material satisfies at least one property selected from a group consisting of the selected material being non-polar, the selected material having at least higher volatility than water, and the selected material having at least lower heat capacity than water.

According to another embodiment, a method for forming a cadmium-sulfide layer on a substrate includes preparing a solution and loading the solution including the one or more alcohols into a pyrolysis-deposition system. The solution uses at least one cadmium-containing solute, at least one sulfur-containing solute, one or more alcohols, and water. And the pyrolysis-deposition system includes one or more nozzles and one or more heating devices. The method for forming a cadmium-sulfide layer on a substrate further includes placing a substrate into the pyrolysis-deposition system, adjusting a distance between the substrate and the one or more nozzles, heating the substrate with the one or more heating devices, and spraying the solution including the one or more alcohols towards the substrate. The method forms a cadmium-sulfide layer on a substrate.

According to yet another embodiment, a system for forming a cadmium-sulfide layer on a substrate includes a liquid supply, a substrate holder, one or more heating devices, and one or more nozzles. The liquid supply provides a solution. The solution includes at least one cadmium-containing solute, at least one sulfur-containing solute, one or more alcohols, and water. The substrate holder is configured to position a substrate. The one or more heating devices are configured to heat the substrate. The one or more nozzles are configured to spray the solution with the one or more alcohols towards the substrate. A distance between the one or more nozzles and the substrate is configured to be adjustable. The system is further configured to form a cadmium-sulfide layer on the substrate using the sprayed solution.

Depending upon the embodiment, one or more of these benefits may be achieved. These benefits and various additional objects, features, and advantages of the present invention can be fully appreciated with reference to the detailed description and accompanying drawings that follow.

### 4. BRIEF DESCRIPTION OF THE DRAWINGS

FIG. 1 is a simplified diagram of a conventional system for deposition of thin films on a substrate using spray pyrolysis.

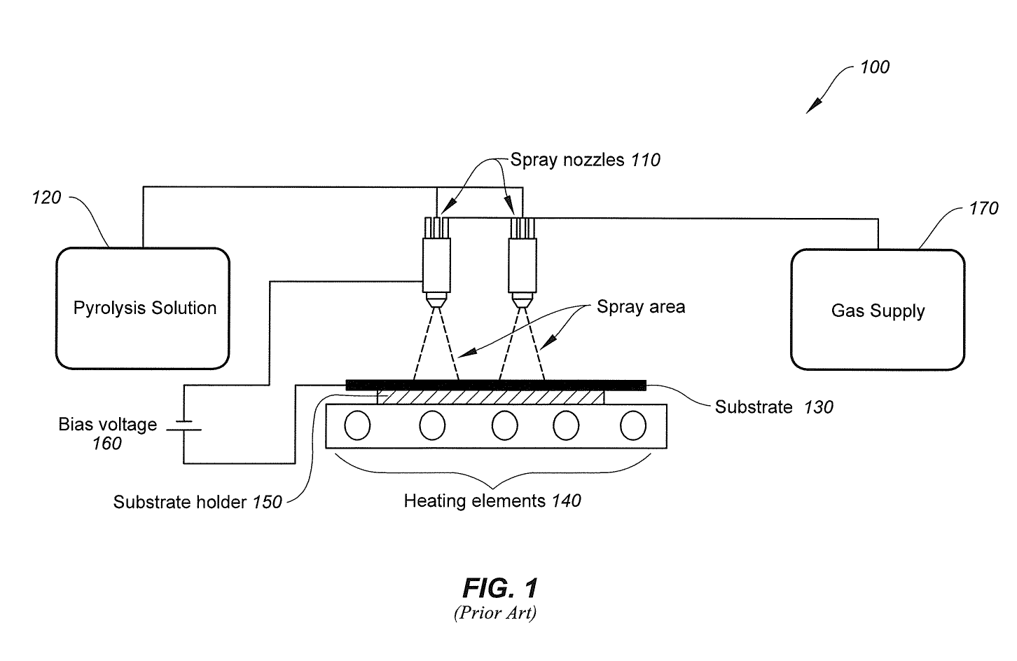

FIG. 2 is a simplified diagram showing heat of vaporization as a function of alcohol concentration in a pyrolysis solution.

FIG. 3 is a simplified diagram showing a method for forming a thin film on a substrate using spray pyrolysis with a spray pyrolysis solution comprising one or more alcohols according to one embodiment of the present invention.

FIG. 4 is a simplified diagram of a system for forming a thin film on a substrate using spray pyrolysis with a spray pyrolysis solution comprising one or more alcohols according to one embodiment of the present invention.

### 5. DETAILED DESCRIPTION OF THE INVENTION

The present invention is directed to deposition of films using spray pyrolysis. More particularly, the invention provides methods and systems for spray pyrolysis with addition of one or more volatile non-polar materials. Merely by way of example, the invention has been applied to the spray pyrolysis of CdS films for photovoltaic modules. But it would be recognized that the invention has a much broader range of applicability.

Improvements in the deposition rate and/or the material utilization of spray pyrolysis are also obtained by altering the material properties of the pyrolysis solution 120. In one embodiment these improvements are obtained by adding to the one or more solvents in the pyrolysis solution 120 one or more materials that have a higher volatility than water, a lower heat capacity than water, and/or a non-polar property. For example, alcohols have a higher volatility than water, a lower heat capacity than water, and a non-polar property. In another example, the one or more added materials are alcohol. In yet another example, the one or more added materials is a combination of different alcohols, including but not limited to methanol, ethanol, and/or isopropyl alcohol. In yet another example, the addition of the one or more materials that have a higher volatility than water, a lower heat capacity than water, and/or a non-polar property favorably adjust the heat capacity of the pyrolysis solution 120.

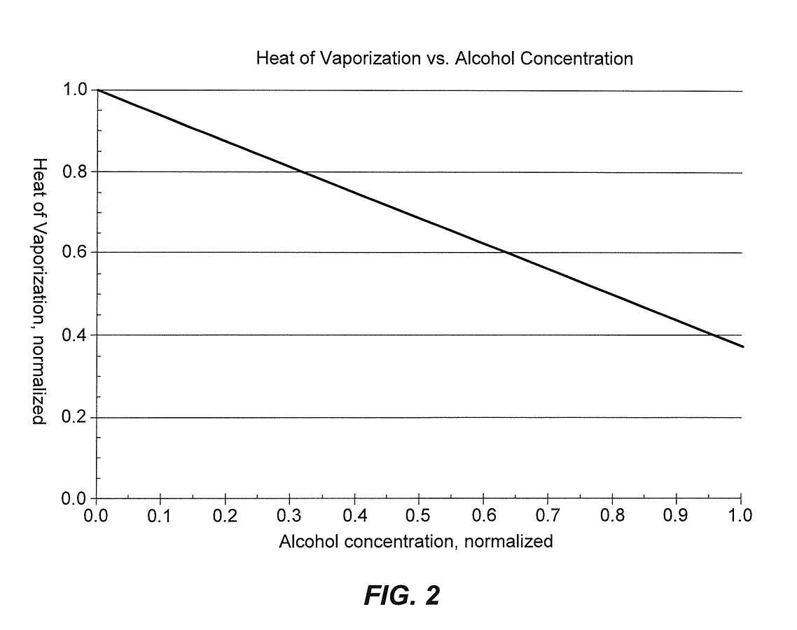

FIG. 2 is a simplified diagram showing heat of vaporization as a function of alcohol concentration in a pyrolysis solution. For example, FIG. 2 demonstrates the effect on the heat of vaporization of the pyrolysis solution as the alcohol concentration, by volume, in the pyrolysis solution is varied. In another example, an alcohol concentration of about 70% by volume in the pyrolysis solution will reduce the heat of vaporization of the pyrolysis solution by almost 50%.

The reduction in the heat of vaporization of the pyrolysis solution with one or more alcohols provides several advantages. For example, the reduction in the heat of vaporization of the pyrolysis solution with one or more alcohols has the advantage of reducing the amount of energy needed to vaporize the pyrolysis solution and gasify the one or more solutes in the pyrolysis solution with one or more alcohols. In one embodiment, this reduction in energy can be used to deposit the same amount of thin film on a surface of a substrate at a lower temperature using the pyrolysis solution with one or more alcohols than would be required with the pyrolysis solution 120, which contains no alcohol. In another embodiment, a higher deposition rate and thus a higher production rate can be obtained without an increase in energy input by using the pyrolysis solution with one or more alcohols in comparison to the pyrolysis solution 120, which contains no alcohol.

In another example, the addition of the one or more alcohols to the pyrolysis solution helps control the locations of the gasification of the solutes between the one or more spray nozzles and the surface of the substrate. In yet another example, the addition of the one or more alcohols to the pyrolysis solution reduces the amount of cooling that occurs when the partially or fully volatized pyrolysis solution with one or more alcohols is deposited on the surface of the substrate. In some embodiments, reduced cooling of the surface of the substrate reduces the likelihood that the substrate will crack. In yet another example, the pyrolysis solution with one or more alcohols reduces the likelihood that the one or more spray nozzles will clog.

In yet another example, the addition of the one or more alcohols to the pyrolysis solution advantageously increases the dielectric constant of the pyrolysis solution. In some embodiments, this improves the charging properties of the droplets of the sprayed pyrolysis solution with one or more alcohols. In certain embodiments, this further increases material utilization when the spray pyrolysis additionally utilizes the bias voltage 160. In some embodiments, the material utilization is improved by 80-95%.

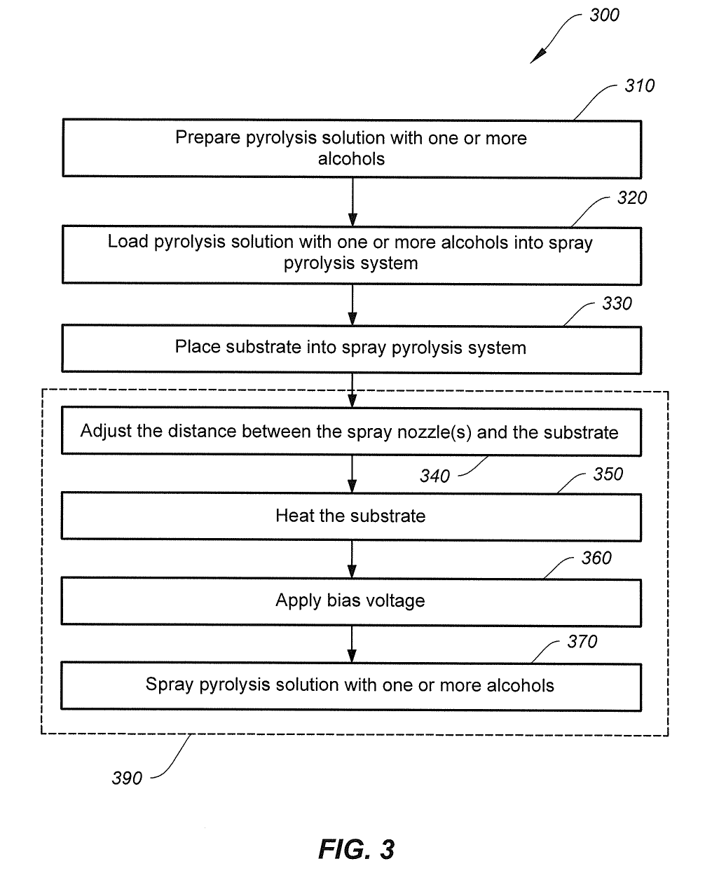

FIG. 3 is a simplified diagram showing a method for forming a thin film on a substrate using spray pyrolysis with a spray pyrolysis solution comprising one or more alcohols according to one embodiment of the present invention. This diagram is merely an example, which should not unduly limit the scope of the claims. One of ordinary skill in the art would recognize many variations, alternatives, and modifications. As shown in FIG. 3, a method 300 of spray pyrolysis includes a process 310 for preparing a pyrolysis solution with one or more alcohols; a process 320 for loading the pyrolysis solution with one or more alcohols into a spray pyrolysis system; a process 330 for placing a substrate into the spray pyrolysis system; a process 340 for adjusting the distance between the one or more spray nozzles and the substrate; a process 350 for heating the substrate; a process 360 for applying a bias voltage; and a process 370 for spraying the pyrolysis solution with one or more alcohols.

At the process 310, a spray pyrolysis solution with one or more alcohols is prepared according to one or more embodiments of the present invention. For example, the pyrolysis solution with one or more alcohols includes one or more solvents. In another example, the one or more solvents include water. In yet another example, the one or more alcohols have a concentration that varies from 5% to 95% by volume. In yet another example, the one or more alcohols include methanol, ethanol, isopropyl alcohol, and/or other alcohols.

In another embodiment, the pyrolysis solution with one or more alcohols includes one or more solutes. For example, the one or more solutes include cadmium chloride (i.e., a cadmium containing solute, e.g., CdCl₂). In another example, the concentration of cadmium chloride varies from 0.001 mol. to 1.0 mol. In yet another example, the one or more solutes includes thiourea (i.e., a sulfur containing solute, e.g., an organosulfur compound SC(NH₂)₂). In yet another example, the concentration of thiourea varies from 0.001 mol. to 1.0 mol. In yet another example, the concentrations of cadmium chloride and thiourea are the same. In yet another example, the concentrations of cadmium chloride and thiourea are different. In yet another example, the pyrolysis solution with one or more alcohols is used to create thin films of cadmium sulfide (i.e., CdS).

In yet another embodiment, the pyrolysis solution with one or more alcohols is heated and stirred. In one example, the pyrolysis solution with one or more alcohols is heated to a temperature between 20-90 degrees centigrade. In another example, the heated pyrolysis solution with one or more alcohols is stirred from 1 minute to 30 minutes.

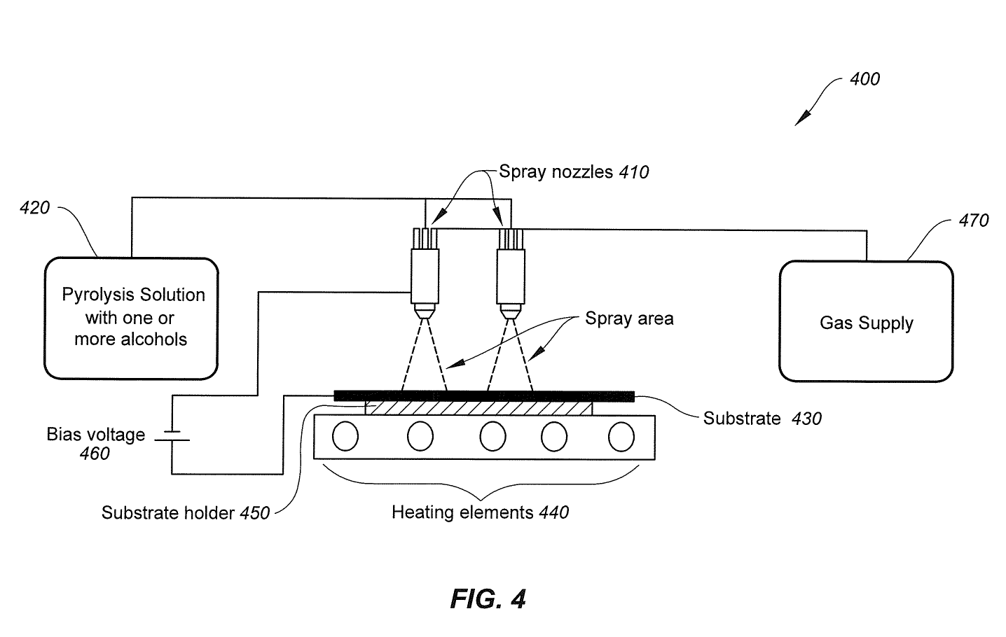

At the process 320 the pyrolysis solution with one or more alcohols is loaded into a spray pyrolysis system. FIG. 4 is a simplified diagram of a system for forming a thin film on a substrate using spray pyrolysis with a spray pyrolysis solution comprising one or more alcohols according to one embodiment of the present invention. This diagram is merely an example, which should not unduly limit the scope of the claims. One of ordinary skill in the art would recognize many variations, alternatives, and modifications. For example, as shown in FIG. 4, the spray pyrolysis system 400 (e.g., pyrolysis-deposition system) includes one or more spray nozzles 410 used to spray a pyrolysis solution with one or more alcohols 420 towards a substrate 430 positioned via a substrate holder 450. In another example, the pyrolysis solution with one or more alcohols is the liquid supply for the spray pyrolysis system 400.

At the process 330, the substrate 430 is placed into the spray pyrolysis system 400 of FIG. 4. For example, the substrate 430 is placed on the substrate holder 450. In another example, the substrate 430 is placed into the substrate holder 450. In yet another example, the substrate holder 450 positions the substrate 430 between the one or more spray nozzles 410 and the one or more heating elements 460 (e.g., heating devices). In yet another example, the substrate 430 could be fed by various automated methods into the spray pyrolysis system 400 for positioning via the substrate holder 450.

At the process 340, the distance between the one or more spray nozzles 410 and the substrate 430 of FIG. 4 is adjusted. For example, the distance between the one or more spray nozzles 410 and the substrate 430 is set based at least in part on the desired properties of the thin film to be created. In yet another example, the distance between the one or more spray nozzles 410 and the substrate 430 is set between 10 cm and 30 cm.

At the process 350, the substrate 430 is heated by the one or more heating elements 440 of FIG. 4. For example, the temperature of the substrate 430 is set based at least in part on the desired properties of the thin film to be created. In another example, the temperature of the substrate 430 is set based at least in part on the desired balance between deposition rate and energy consumption. In yet another example, the substrate 430 is heated to a temperature between 280° C. and 500° C.

At the process 360, a bias voltage 460 is optionally applied between the one or more spray nozzles 410 and the substrate 430 of FIG. 4. For example, the bias voltage 460 is set based at least in part on the desired properties of the thin film to be created. In another example, the bias voltage 460 is set based at least in part on a desired material utilization requirement. In yet another example, the bias voltage 460 is set in the range of 500 volts to 10 kilovolts.

At the process 370, the pyrolysis solution with one or more alcohols 420 is sprayed using the one or more spray nozzles 410 of FIG. 4. In one example, a single spray nozzle 410 is utilized to spray the pyrolysis solution with one or more alcohols 420 to create the thin film on the substrate 430. In another example, multiple spray nozzles 410 are utilized to create the thin film on the substrate 430. In yet another example, atomization of the pyrolysis solution with one or more alcohols 420 at the point of each of the one or more spray nozzles 410 is created using gas, mechanical, and/or hydraulic atomization techniques. In yet another example, the spray rate of the pyrolysis solution with one or more alcohols 420 is constant. In yet another example, the spray rate of the pyrolysis solution with one or more alcohols 420 is modulated between two or more spray rates. In yet another example, the one or more spray rates and/or spray durations is set based at least in part on the desired properties of the thin film to be created. In yet another example, the one or more spray rates is between 1 ml/min and 100 ml/min. In yet another example, the spray duration is between 30 seconds and 40 minutes. In yet another example, the deposition rate of the thin film is monitored during spraying to control the thin film created.

According to one embodiment, as one or more droplets of the pyrolysis solution with one or more alcohols 420 approach the surface of the substrate 430, the one or more solvents and the one or more alcohols vaporize and the one or more solutes become one or more vapors. Then, the one or more vapors form a film on the surface of the substrate 430. In another embodiment, one or more droplets of the pyrolysis solution with one or more alcohols 420 reach the surface of the substrate 430. Then, with the one or more solvents and/or the one or more alcohols still present in the pyrolysis solution 420 on the surface of the substrate 430, a film is formed on the surface of the substrate 430 as the one or more solvents and the one or more alcohols in the pyrolysis solution 420 vaporize. In yet another embodiment, vaporization both between the one or more spray nozzles 410 and the substrate 430 and on the surface of the substrate 430 occurs in the same deposition process. In yet another embodiments, spray pyrolysis also utilizes a gas supply 470 made available to the one or more spray nozzles 410. For example, the gas supply 470 is used to atomize the pyrolysis solution 420. In another example, the gas supply 470 controls the flow of the pyrolysis solution 420 through the one or more spray nozzles 410 towards the substrate 430. In yet another example, nitrogen gas is provided by the gas supply 470.

According to some embodiments, the processes 340, 350, 360, and 370 collectively form a pyrolysis process 390. In certain embodiments, each of the parameters in the pyrolysis process 390 is mutually dependent upon each other. In some embodiments, each of the parameters in the pyrolysis process 390 are set based at least in part on the desired properties of the thin film to be created. For example, depending upon the thin film desired, the distance between the one or more spray nozzles 410 and the substrate 430, the temperature of the substrate 430, the optional bias voltage between the one or more spray nozzles 410 and the substrate 430, and the spray rate and duration are set based in part on each other and the properties of the pyrolysis solution with one or more alcohols 420 being used. In another example, the pyrolysis solution 420 includes a 50% concentration by volume of the one or more alcohols, a cadmium chloride concentration of 0.1 mol., and a thiourea concentration of 0.1 mol., and the pyrolysis solution is sprayed with a flow rate of 8 ml/min. for five minutes towards the substrate 430 that is heated to 350° C. with a distance of 20 cm between the one or more spray nozzles 410 and the substrate 430 and with a bias voltage 460 of 1000 volts, resulting a cadmium sulfide film of approximately 150 nm.

As discussed above and further emphasized here, FIGS. 3 and 4 are merely examples, which should not unduly limit the scope of the claims. One of ordinary skill in the art would recognize many variations, alternatives, and modifications. For example, the pyrolysis solution with one or more alcohols 420 is but one pyrolysis solution suitable for use in the present invention. In another example, the one or more alcohols in the pyrolysis solution are replaced with one or more materials that have a higher volatility than water, a lower heat capacity than water, and/or a non-polar property. In yet another example, in addition to the one or more alcohols, one or more materials that have a higher volatility than water, a lower heat capacity than water, and/or a non-polar property are added to the pyrolysis solution. In yet another example, the method 300 of spray pyrolysis can be used for the manufacturing of photodiodes. In yet another example, the method as shown in FIG. 3 and/or the system as shown in FIG. 4 are not limited to forming a thin film, but rather can also be used to form other types of layers.

According to at least one embodiment, a method for forming a cadmium-sulfide layer (e.g., a cadmium-sulfide thin film) on a substrate includes preparing a solution and loading the solution into a pyrolysis-deposition system. The solution uses at least one cadmium-containing solute, at least one sulfur-containing solute, water, and at least one selected material. And the pyrolysis-deposition system includes one or more nozzles and one or more heating devices. The method for forming a cadmium-sulfide layer on a substrate further includes placing a substrate into the pyrolysis-deposition system, adjusting a distance between the substrate and the one or more nozzles, heating the substrate with the one or more heating devices, and spraying the solution including the selected material towards the substrate. The method forms a cadmium-sulfide layer on a substrate. The selected material satisfies at least one property selected from a group consisting of the selected material being non-polar, the selected material having at least higher volatility than water, and the selected material having at least lower heat capacity than water. For example, the method for forming a cadmium-sulfide layer on a substrate is implemented according to at least FIG. 3 and/or FIG. 4.

In another example, the selected material is non-polar, has higher volatility than water, and has lower heat capacity than water.

According to another embodiment, a method for forming a cadmium-sulfide layer (e.g., a cadmium-sulfide thin film) on a substrate includes preparing a solution and loading the solution including the one or more alcohols into a pyrolysis-deposition system. The solution uses at least one cadmium-containing solute, at least one sulfur-containing solute, one or more alcohols, and water. And the pyrolysis-deposition system includes one or more nozzles and one or more heating devices. The method for forming a cadmium-sulfide layer on a substrate further includes placing a substrate into the pyrolysis-deposition system, adjusting a distance between the substrate and the one or more nozzles, heating the substrate with the one or more heating devices, and spraying the solution including the one or more alcohols towards the substrate. The method forms a cadmium-sulfide layer on a substrate. For example, the method for forming a cadmium-sulfide layer on a substrate is implemented according to at least FIG. 3 and/or FIG. 4.

In another example, preparing a solution using at least one cadmium-containing solute, one sulfur-containing solute, one or more alcohols, and water includes heating the solution to a temperature of between 20° C. and 90° C. and stirring the solution for a period of between 1 minute and 30 minutes. In yet another example, a concentration of the one or more alcohols in the solution is between 5 percent and 95 percent by volume. In yet another example, the one or more alcohols are selected from a group consisting of methanol, ethanol, and isopropyl alcohol. In yet another example, a first concentration of the at least one cadmium-containing solute is between 0.001 mol. and 1.0 mol., and a second concentration of the at least one sulfur-containing solute is between 0.001 mol. and 1.0 mol. In yet another example, the first concentration of the at least one cadmium-containing solute and the second concentration of the at least one sulfur-containing solute are the same. In yet another example, the at least one cadmium-containing solute includes cadmium chloride and the at least one sulfur-containing solute includes thiourea.

In yet another example, the solution includes a solvent fraction, an alcohol fraction, and a solute fraction. The solvent fraction includes water. The alcohol fraction includes the one or more alcohols. And the solute fraction includes the at least one cadmium-containing solute and the at least one sulfur-containing solute. The alcohol fraction is present in a first concentration of between 5 percent and 95 percent by volume. The at least one cadmium-containing solute is present in a second concentration of between 0.001 mol. and 1.0 mol. The at least one sulfur-containing solute is present in a third concentration of between 0.001 mol. and 1.0 mol.

In yet another example, the solution consists of water, the one or more alcohols, the at least one cadmium-containing solute, and the at least one sulfur-containing solute. The one or more alcohols are present in a first concentration of between 5 percent and 95 percent by volume. The at least one cadmium-containing solute is present in a second concentration of between 0.001 mol. and 1.0 mol. The at least one sulfur-containing solute is present in a third concentration of between 0.001 mol. and 1.0 mol.

In yet another example, spraying the solution including the one or more alcohols towards the substrate includes atomizing the solution. In yet another example, forming a cadmium-sulfide layer from the sprayed solution on the substrate includes vaporizing the solution. In yet another example, the method further includes applying a bias voltage between the one or more nozzles and the substrate.

According to yet another embodiment, a system for forming a cadmium-sulfide layer (e.g., a cadmium-sulfide thin film) on a substrate includes a liquid supply, a substrate holder, one or more heating devices, and one or more nozzles. The liquid supply provides a solution. The solution includes at least one cadmium-containing solute, at least one sulfur-containing solute, one or more alcohols, and water. The substrate holder is configured to position a substrate. The one or more heating devices are configured to heat the substrate. The one or more nozzles are configured to spray the solution with the one or more alcohols towards the substrate. A distance between the one or more nozzles and the substrate is configured to be adjustable. The system is further configured to form a cadmium-sulfide layer on the substrate using the sprayed solution. For example, the system for fanning a cadmium-sulfide layer on a substrate is implemented according to at least FIG. 3 and/or FIG. 4.

In another example, the system further includes a voltage supply configured to provide a bias voltage between the one or more nozzles and the substrate.

In yet another example, the solution includes a solvent fraction, an alcohol fraction, and a solute fraction. The solvent fraction includes water. The alcohol fraction includes the one or more alcohols. And the solute fraction includes the at least one cadmium-containing solute and the at least one sulfur-containing solute. The alcohol fraction is present in a first concentration of between 5 percent and 95 percent by volume. The at least one cadmium-containing solute is present in a second concentration of between 0.001 mol. and 1.0 mol. The at least one sulfur-containing solute is present in a third concentration of between 0.001 mol. and 1.0 mol.

In yet another example, the solution consists of water, the one or more alcohols, the at least one cadmium-containing solute, and the at least one sulfur-containing solute. The one or more alcohols are present in a first concentration of between 5 percent and 95 percent by volume. The at least one cadmium-containing solute is present in a second concentration of between 0.001 mol. and 1.0 mol. The at least one sulfur-containing solute is present in a third concentration of between 0.001 mol. and 1.0 mol.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A method for forming a cadmium-sulfide layer on a substrate, the method comprising:
preparing a solution using at least one cadmium-containing solute, at least one sulfur-containing solute, water, and at least one selected material;
loading the solution including the selected material into a pyrolysis-deposition system, the pyrolysis-deposition system including one or more nozzles and one or more heating devices;
placing a substrate into the pyrolysis-deposition system;
adjusting a distance between the substrate and the one or more nozzles;
heating the substrate with the one or more heating devices;
spraying the solution including the selected material towards the substrate; and
forming a cadmium-sulfide layer from the sprayed solution on the substrate;
wherein the selected material satisfies at least one property selected from a group consisting of the selected material being non-polar, the selected material having at least higher volatility than water, and the selected material having at least lower heat capacity than water.

2. The method of claim 1 wherein the selected material is non-polar, has higher volatility than water, and has lower heat capacity than water.

3. A method for forming a cadmium-sulfide layer on a substrate, the method comprising:
preparing a solution using at least one cadmium-containing solute, at least one sulfur-containing solute, one or more alcohols, and water;
loading the solution including the one or more alcohols into a pyrolysis-deposition system including one or more nozzles and one or more heating devices;
placing a substrate into the pyrolysis-deposition system;
adjusting a distance between the substrate and the one or more nozzles;
heating the substrate with the one or more heating devices;
spraying the solution including the one or more alcohols towards the substrate; and
forming a cadmium-sulfide layer from the sprayed solution on the substrate.

4. The method of claim 3 wherein the process for preparing a solution using at least one cadmium-containing solute, one sulfur-containing solute, one or more alcohols, and water includes:
heating the solution to a temperature of between 20° C. and 90° C.; and
stirring the solution for a period of between 1 minute and 30 minutes.

5. The method of claim 3 wherein a concentration of the one or more alcohols in the solution is between 5 percent and 95 percent by volume.

6. The method of claim 3 wherein the one or more alcohols are selected from a group consisting of methanol, ethanol, and isopropyl alcohol.

7. The method of claim 3 wherein:
a first concentration of the at least one cadmium-containing solute is between 0.001 mol. and 1.0 mol.; and
a second concentration of the at least one sulfur-containing solute is between 0.001 mol. and 1.0 mol.

8. The method of claim 7 wherein the first concentration of the at least one cadmium-containing solute and the second concentration of the at least one sulfur-containing solute are the same.

9. The method of claim 3 wherein:
the at least one cadmium-containing solute includes cadmium chloride; and
the at least one sulfur-containing solute includes thiourea.

10. The method of claim 3 wherein the solution consists of:
a solvent fraction comprising water;
an alcohol fraction comprising the one or more alcohols; and
a solute fraction comprising the at least one cadmium-containing solute and the at least one sulfur-containing solute;
wherein:
the alcohol fraction is present in a first concentration of between 5 percent and 95 percent by volume;
the at least one cadmium-containing solute is present in a second concentration of between 0.001 mol. and 1.0 mol.; and
the at least one sulfur-containing solute is present in a third concentration of between 0.001 mol. and 1.0 mol.

11. The method of claim 3 wherein the solution consists of:
water;
the one or more alcohols; and
the at least one cadmium-containing solute; and
the at least one sulfur-containing solute;
wherein:
the one or more alcohols are present in a first concentration of between 5 percent and 95 percent by volume;
the at least one cadmium-containing solute is present in a second concentration of between 0.001 mol. and 1.0 mol.; and
the at least one sulfur-containing solute is present in a third concentration of between 0.001 mol. and 1.0 mol.

12. The method of claim 3 wherein the process for spraying the solution including the one or more alcohols towards the substrate includes atomizing the solution.

13. The method of claim 3 wherein the process for forming a cadmium-sulfide layer from the sprayed solution on the substrate includes vaporizing the solution.

14. The method of claim 3, and further comprising: applying a bias voltage between the one or more nozzles and the substrate.

15. A system for forming a cadmium-sulfide layer on a substrate, the system comprising:
a liquid supply for providing a solution comprising at least one cadmium-containing solute, at least one sulfur-containing solute, one or more alcohols, and water;
a substrate holder configured to position a substrate;
one or more heating devices configured to heat the substrate; and
one or more nozzles configured to spray the solution with the one or more alcohols towards the substrate;
wherein a distance between the one or more nozzles and the substrate is configured to be adjustable;
wherein the system is further configured to form a cadmium-sulfide layer on the substrate using the sprayed solution.

16. The system of claim 15, and further comprising a voltage supply configured to provide a bias voltage between the one or more nozzles and the substrate.

17. The system of claim 15 wherein the solution consists of:
a solvent fraction comprising water;
an alcohol fraction comprising the one or more alcohols; and
a solute fraction comprising the at least one cadmium-containing solute and the at least one sulfur-containing solute;
wherein:
the alcohol fraction is present in a first concentration of between 5 percent and 95 percent by volume;
the at least one cadmium-containing solute is present in a second concentration of between 0.001 mol. and 1.0 mol.; and
the at least one sulfur-containing solute is present in a third concentration of between 0.001 mol. and 1.0 mol.

18. The system of claim 15 wherein the solution consists of:
water;
the one or more alcohols; and
the at least one cadmium-containing solute; and
the at least one sulfur-containing solute;
wherein:
the one or more alcohols are present in a first concentration of between 5 percent and 95 percent by volume;
the at least one cadmium-containing solute is present in a second concentration of between 0.001 mol. and 1.0 mol.; and
the at least one sulfur-containing solute is present in a third concentration of between 0.001 mol. and 1.0 mol.
